(19) United States
(12) Patent Application Publication
(10) Pub. No.: US 2009/0150610 A1
(43) Pub. Date: Jun. 11, 2009

(54) TWO-IN-ONE MEMORY CARD

(76) Inventors: Chun-Wei HSU, Taipei Hsien (TW); Cheng-Hsiung Liao, Taipei Hsien (TW)

Correspondence Address: HDLS Patent & Trademark Services, P.O. BOX 220746, CHANTILLY, VA, 20153-0746, US

(21) Appl. No.: 11/950,713

(22) Filed: Dec. 5, 2007

(51) Int. Cl. G06F 12/00; H05K 5/00; G11C 5/14

(52) U.S. Cl. 711/115; 365/226; 711/E12.001

(57) ABSTRACT

Two independent terminal areas and a memory unit are contained in a single casing and provided for users to use a memory card separately. A terminal area is disposed separately on two corresponding sides of the memory card, and a control circuit and two memories are installed in the memory card, and the control circuit controls the two memories, and each of the two memories is connected to one of the terminal areas to form an independent data access path, so as to achieve the effect of using a casing of a single memory card to provide an application mode and a capacity of a double memory card.

### BACKGROUND OF THE INVENTION

1. Field of the Invention

The present invention relates to a storage device, and more particularly to a memory card.

2. Description of Prior Art

In recent years, digital products such as digital cameras, mobile phones, electronic dictionaries, digital photo frames, MP3 players and other 3C products become popular and indispensable to our daily life, and consumers rely increasingly more on these products.

The aforementioned digital products require built-in memories for storing data, but the memory capacity is generally not large enough due to the internal circuit layout and manufacturing cost of the products, and some products even have no built-in memory at all, and consumers have to prepare an external memory card for data storage, or use the external memory card to expand the memory capacity if the built-in memory cannot satisfy the consumer requirements. To meet the requirements of modern digital products, manufacturers need to produce memories with a large storage capacity.

At present, various types of memory cards are available in the market, and some of the popular ones include Compact Flash (CF), Multi Media Card (MMC), Memory Stick (MS), Secure Digital (SD), and many others, and the SD card which is the most popular one among the aforementioned memory cards is used for illustrating the present invention as follows.

Referring to FIGS. 1A and 1B for a front view and a rear view of a traditional SD memory card respectively, the traditional memory card 1 has a single terminal area 11 for users to insert the single-sided memory card 1 into the corresponding memory card slot for accessing data in the memory card 1.

Referring to FIG. 2 for a block diagram of an internal layout of a prior art memory card, the memory card comprises a terminal area 11, a power detector 12, a processor 13, a memory controller 14 and a memory 15, such that if the terminal area 11 of the memory card 1 is inserted into an external device (not shown in the figure) including a memory card slot of a digital device such as a digital camera and an electronic dictionary, and the apparatus successfully reads the memory card 1, a power source will be supplied to turn on the power detector 12 and electrically connected to the processor 13. If any access of the memory 15 is performed by them, the processor 13 will send an instruction to the memory controller 14, and the memory controller 14 will electrically connect the memory 15 for accessing the memory 15.

As IC fabrication processes advance, the capacity of a single memory card becomes increasingly larger. However, various memory cards and corresponding card readers are manufactured according to different protocols, and the present SD card specifications specified by the Card Association (SDA) are divided mainly into the following two types:

1. Version SD1.1 is an old version of the SD card specification with a maximum capacity of 2 GB.

2. Version SD2.0 is a version of a SDHC (SD High Capacity) card with a capacity of 2 GB or above.

As SDA is developed with the fast pace of the memory card, new memory card specifications are established one by one, and the transmission rate of the SDHC card is higher than that of the traditional SD card, such that the SD card not only has a large capacity of over 2 GB, but also gives an appearance of the traditional SD card. The volume or thickness of the SD card will not be increased by the increase of capacity, and thus the latest developed digital products usually come with a specification having such memory card slot.

However, the aforementioned new specification causes consumers lots of troubles to use the memory card, even when the specification of the SD card is upgraded to Version 2.0. Since many of the present digital products such as digital cameras available in the market still go with a memory card slot of SD1.1 version, and the specification of the SD card is backward compatible, therefore the memory card slot of the digital camera of the old SD1.1 version only reads a memory card of the SD1.1 version and cannot read a memory card of the SDHC version. In other words, the maximum capacity of the memory card provided for the use of these digital cameras is 2 GB, and if a user needs to use a capacity greater than 2 GB, then the user has to prepare an additional memory card, and thus making the application very inconvenient. As to users who like to take pictures outdoors, it is very inconvenient to carry two or even more memory cards with them all the time.

The aforementioned shortcoming can be overcome when a consumer upgrades the product to be compatible with the new specification of the memory card with a large capacity, but it is not cost-effective for consumers to buy the whole set of equipment simply for upgrading the memory card specification. Only a minority of consumers will do so, and a vast majority of consumers will continue using the old model, and the aforementioned shortcoming will remain. Obviously, the limitation of memory capacity to 2 GB is a major drawback of most digital products, particularly the digital camera that requires a memory card of a large capacity.

In view of the foregoing shortcomings of the prior art, the inventor of the present invention based on years of experience in the related industry to conduct extensive researches and experiments, and finally developed a two-in-one memory card in accordance with the present invention to effectively overcome the shortcomings of the prior art.

### SUMMARY OF THE INVENTION

It is a primary objective of the present invention to provide a memory card whose casing contains two independent terminal areas and a memory unit, so that if a digital product selected by a consumer is limited by a new specification, and the reading capacity is limited, the consumer can carry a single memory card to double the storage space of the memory card, and use the space of a single card to provide an application mode and a capacity for a double card.

To achieve the foregoing objectives, the present invention provides a memory card having a terminal area disposed separately on two corresponding sides of the memory card, a control circuit and two memories disposed in the memory card, and the control circuit controls the two memories, and one of the two memories is connected to one of the terminal areas to form an independent data access path.

### BRIEF DESCRIPTION OF DRAWINGS

FIG. 1A is a front view of a prior art memory card;

FIG. 1B is a rear view of a prior art memory card;

FIG. 2 is a block diagram of an internal layout of a prior art memory card;

FIG. 3A is a front view of the present invention;

FIG. 3B is a rear view of the present invention;

FIG. 4 is a schematic block diagram of an internal layout of a first preferred embodiment of the present invention;

FIG. 5 is a schematic view of the concept of a first preferred embodiment of the present invention;

FIG. 6 is a schematic block diagram of an internal layout of a second preferred embodiment of the present invention;

FIG. 7 is a schematic view of the concept of a second preferred embodiment of the present invention;

FIG. 8 is a schematic block diagram of an internal layout of a third preferred embodiment of the present invention;

FIG. 9A is a schematic view of the concept of a third preferred embodiment of the present invention; and

FIG. 9B is a schematic view of another concept of a third preferred embodiment of the present invention.

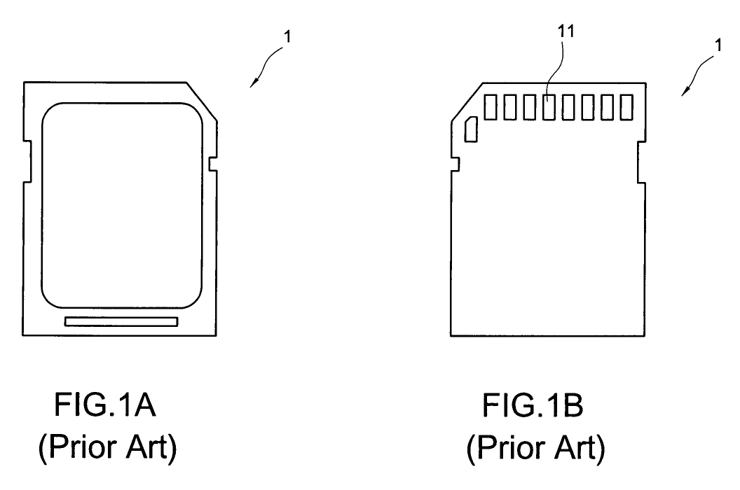

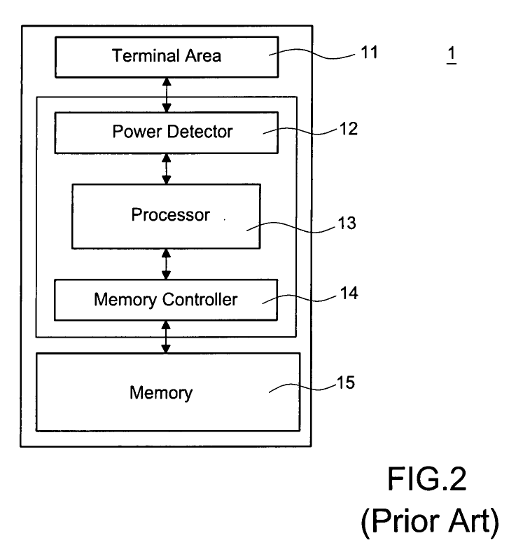

### DETAILED DESCRIPTION OF THE INVENTION

The technical characteristics, features and advantages of the present invention will become apparent in the following detailed description of the preferred embodiments with reference to the accompanying drawings.

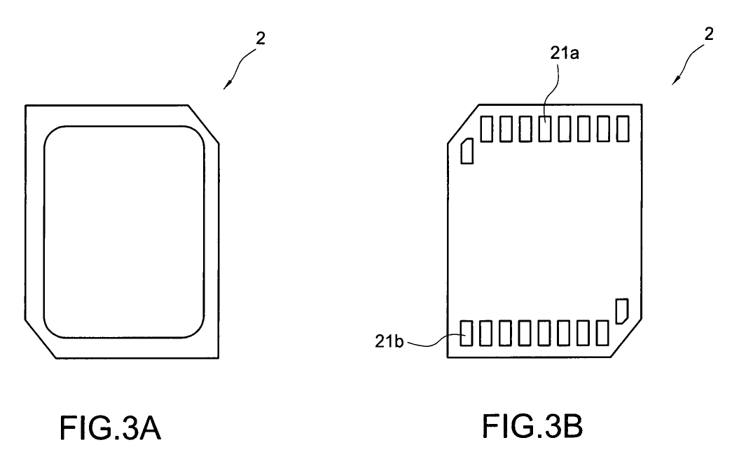

Referring to FIGS. 3A and 3B for a front view and a rear view of the present invention respectively, the invention is characterized in that the memory card 2 comprises two independent terminal areas 21a, 21b disposed on two corresponding sides of the memory card 2 and two memories installed in the memory card 2 to achieve the effect of using a casing of the single memory card 2 to provide an application mode and a capacity of a double memory card. The memory used in the invention is a non-volatile memory including but not limited to a flash memory. To achieve the aforementioned effect, it is necessary to design two independent data access paths in the memory card 2, so that the two memories in the memory card 2 can be accessed by an external device through the two terminal areas 21a, 21b, and the internal layout of the memory card 2 can be divided into three main types: one control circuit corresponding to one memory, one control circuit corresponding to two memories, and two control circuits corresponding to two memories, and the control circuit contains a processor, a power detector and a memory controller, and the circuits are described by the following embodiments.

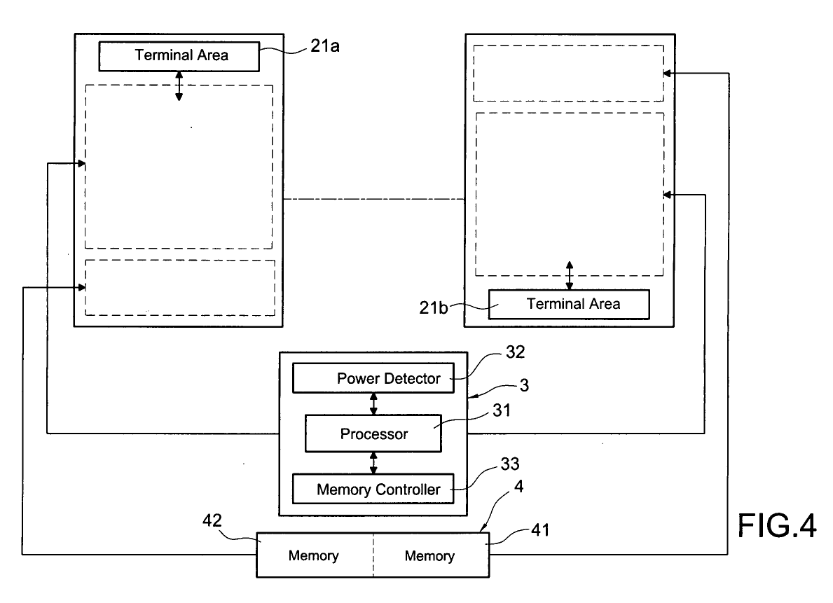

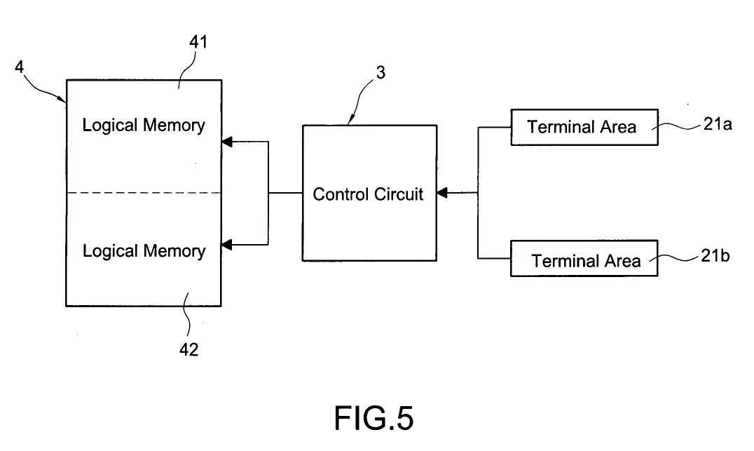

Referring to FIGS. 4 and 5 for a schematic block diagram and a schematic concept view of a first preferred embodiment of the present invention, a control circuit 3 corresponds to a memory 4, and a firmware (not shown in the figure) in a memory card 2 has a flag, converts a physical memory into a logical memory, and divides a physical memory 4 into two memories 41, 42. If the first terminal area 21a is inserted and used by an external device, the power detector 32 will be turned on, and the value of the flag 5 will be set to 0. If the processor 31 detects that the value of the flag 5 is equal to 0, then the pointer will be pointed to the first memory 41, and if the processor 31 has received an access instruction by then, the processor 31 will send a control instruction to the memory controller 33 which is connected to the first memory 41 for accessing the first memory 41. If the second terminal area 21b is used, the power detector 32 will be turned on, and the value of the flag 5 will be set to 1. If the processor 31 detects that the value of the flag 5 is equal to 1, then the pointer will be pointed to the second memory 42, and if the processor 31 has received an access instruction, the processor 31 will send a control instruction to the memory controller 33 which is connected to the second memory 42 for accessing the second memory 42. Though the memory card 2 contains a physical memory 4, the foregoing mechanism designs the memory 4 for the use of two memories, and the two terminal areas 21a, 21b can be used for providing two independent access systems of the memory card 2.

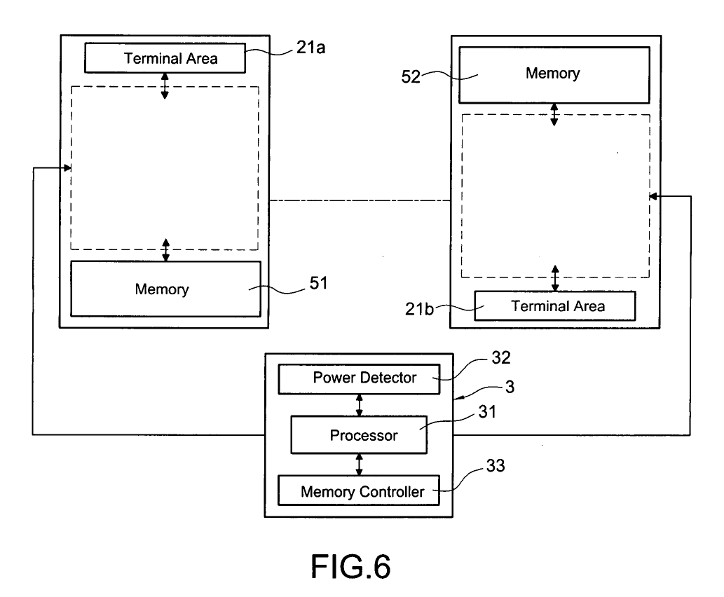

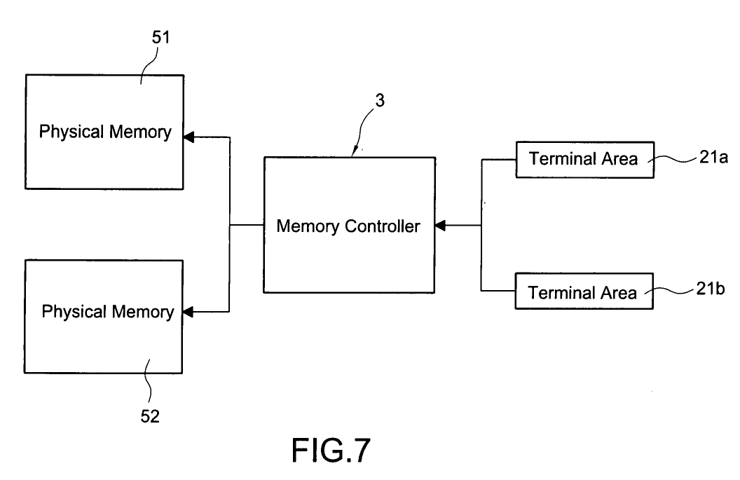

Although the aforementioned embodiment is feasible since the design of a single memory 4 can save the fixed area inside the casing of the memory card 2, yet the method of dividing and simulating a single memory 4 into two logical memories 41, 42 will increase the level of difficulty of the circuit layout and firmware design. Therefore, the inventor of the present invention provides another solution as illustrated in the following embodiment. Referring to FIGS. 6 and 7 for a schematic block diagram and a schematic concept view of a second preferred embodiment of the present invention, the difference of a method of installing a control circuit 3 corresponding to two memories 51, 52 with the method of the aforementioned embodiment resides on that this embodiment has two physical memories 51, 52 in the memory card 2 instead of a single memory, and two logical memories are formed by division and simulation, and such arrangement simply uses a control circuit to distinguish the two memories 51, 52 without using a flag installed in the firmware of the memory card 2. In addition, the layout of hardware circuits is much simpler. The control circuit 3 is connected to the first terminal area 21a and the first memory 51 to form an access path, and also connected to the second terminal area 21b and the second memory 52 to form another access path. When the first terminal area 21a on the memory card is used and the processor 31 has received an access instruction, then the first memory 51 can be accessed. When the second terminal area 21b on the memory card 2 is used, and the processor 31 has received an access instruction, then the second memory 52 can be accessed.

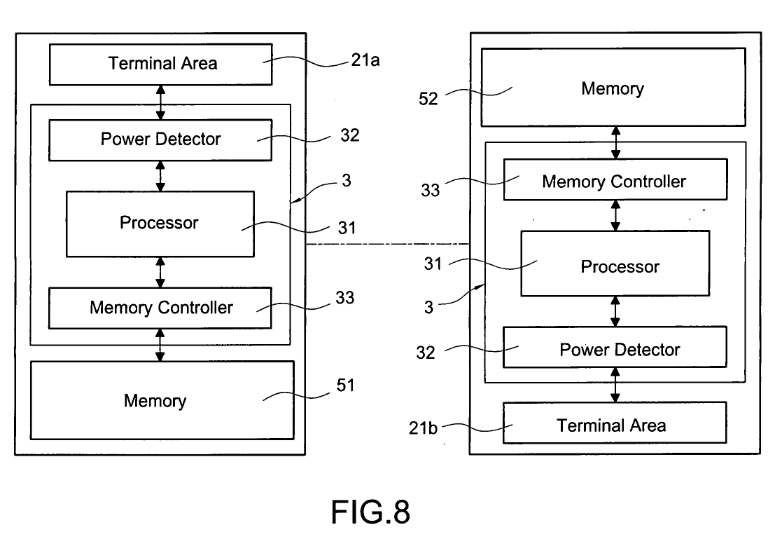

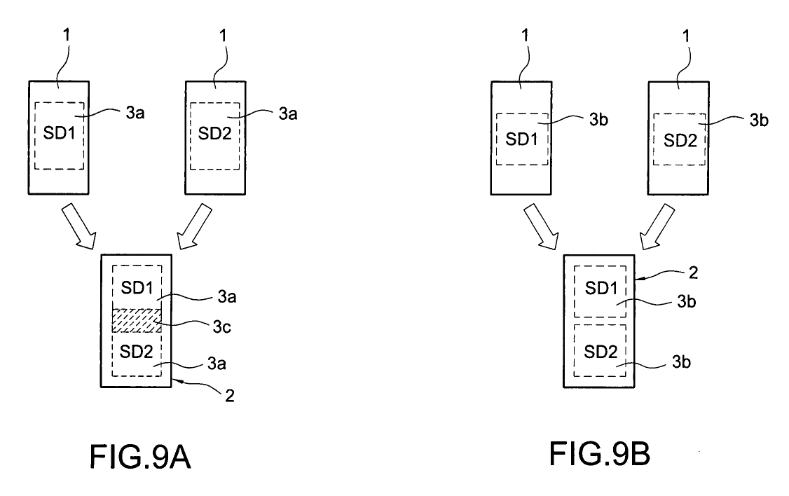

Referring to FIG. 8 a schematic block diagram of an internal layout of another preferred embodiment of the present invention, this embodiment (which is compared with the aforementioned two embodiments) combines all components in the memory card 1 into a fixed area inside a casing of the single memory card 2 instead of omitting any of the components. The method of installing two control circuits corresponding to two memories is much simpler than the method of using a control circuit corresponding to two memories, but it is noteworthy to point out that such arrangement must improve the hardware circuit design to avoid interference between hardware or data access error, if all components of the two memory cards are installed in the casing of the single memory card. Therefore, this embodiment densely installs all components of two memory cards into a fixed area of the casing of the single memory card. There are two main solutions for different integrated circuits (IC) in the memory cards. In FIG. 9A, the IC 3a used in the memory card is larger and all components in the two memories card cannot be installed densely into the casing of the memory card 2, and thus all or some of the components of the two memories card 1 are stacked to achieve the effect. However, this method has to keep the height of an overlapped portion 3c within an acceptable range such as 2.1 mm for the SDA card after the components of the two memory cards are stacked, and thus manufacturers have to select the IC components carefully. In another solution, a smaller IC component 3b such as a chip die is selected to make it easier to densely install and stack all components of the two memories card 1 in the casing of the single memory card 2 or even achieve the effect of providing an application mode and a capacity of a double card by the space of a single card without the need of stacking the components at all. In this embodiment, the inventor's experiment result is used for illustrating the invention, but the persons skilled in the art should know the circuit layout may be changed according to the using requirements and consideration.

If a digital product used by a consumer is of old specification such as a digital camera of the SD1.1 specification, a SD card with a capacity of 2 GB or below should be used. If the consumer wants to use a larger capacity, then the consumer has to carry an additional memory card. The capacity of 2 GB is insufficient for the consumer requirements as the resolution and file size are increased in these days, and thus consumers using the old models of digital cameras usually have to carry two or more memory cards with them to meet the application requirements, and thus making the application very inconvenient. If consumers select using the memory card of the invention, then a memory card with a capacity of 4 GB can be used since the memory card is composed of two separate memory units with 2 GB each, and the memory units are combined into the casing of the single memory card, such the first terminal area of the memory card can be inserted into the memory card slot of a digital product to access the first memory corresponding to the first terminal area. If the memory card is removed, and the second terminal area of the memory card is inserted for its use, then the second memory corresponding to the second terminal area can be accessed. Therefore, the user no longer need to carry an additional memory card for using a space of 4 GB, and such application is definitely a long desired need of consumers.

While the invention is described by examples and in terms of preferred embodiments, it is to be understood that the invention is not limited thereto. On the contrary, the aim is to cover all modifications, alternatives and equivalents falling within the spirit and scope of the invention as defined by the appended claims.

What is claimed is:

1. A two-in-one memory card, comprising:
a casing;
two terminal areas, separately disposed on a surface of the casing, for connecting an external device;
a control circuit, installed in the casing, and electrically coupled with the two terminal areas;
two memories, installed in the casing, and electrically coupled with the control circuit;
wherein the two memories are controlled by the control circuit, and combined separately with a terminal area to form a single data access path, such that the single casing can be used for two independent memory cards.

2. The memory card of claim 1, wherein the control circuit comprises:
a power detector, electrically coupled to the two terminal areas, for receiving a power supply from the external device and detecting whether the first terminal area or the second terminal area is triggered;
a processor, electrically coupled to the power detector, for determining whether to use the first memory or the second memory for the memory, and issuing a control instruction after one of the two terminal areas is triggered; and
a memory controller, electrically coupled to the processor, for receiving the control instruction from the processor after the control instruction is converted into a language acceptable to the two memories, and electrically coupled to the first memory or the second memory corresponding to the control instruction for transmitting instructions and data.

3. The memory card of claim 1, wherein the two terminal areas have the same terminal area.

4. The memory card of claim 1, wherein the two memories are flash memories.

5. The memory card of claim 4, wherein the two memories are two separate physical memories.

6. The memory card of claim 4, wherein the two memories are two logical memories formed by dividing a physical memory.

7. A two-in-one memory card, comprising:
a casing;
two terminal areas, being a first terminal area and a second terminal area respectively disposed on a surface of the casing for connecting an external device;
two control circuits, separately installed in the casing, and being a first control circuit electrically coupled to the first terminal area and a second control circuit electrically coupled to the second terminal area respectively;
two memories, installed in the casing, and being a first memory electrically coupled to the first control circuit and a second memory electrically coupled to the second control circuit respectively;
wherein the two control circuits separately control a memory, and combine the corresponding terminal areas into a single data access path, such that the single casing can be used by the two independent memory cards.

8. The memory card of claim 7, wherein the two control circuits further comprise:
a power detector, electrically coupled to the terminal area, for receiving a power supply from the external device to determine whether or not the terminal area is triggered;
a processor, electrically coupled to the power detector, for issuing a control instruction after the terminal area is triggered; and
a memory controller, electrically coupled to the processor, for converting the control instruction from the processor into a language acceptable to the memory, and electrically coupled to the memory for transmitting instructions and data.

9. The memory card of claim 7, wherein the two terminal areas have the same terminal area.

10. The memory card of claim 7, wherein the two memories are flash memories.
